(19) United States
(12) Patent Application Publication
(10) Pub. No.: US 2026/0130048 A1
(43) Pub. Date: May 7, 2026

(54) DISPLAY PANEL, ELECTRONIC DEVICE INCLUDING THE SAME, AND METHOD OF MANUFACTURING DISPLAY PANEL

(71) Applicant: Samsung Display Co., Ltd., Yongin-si (KR)

(72) Inventors: Nguyen Thanh Tien, Yongin-si (KR); Doona Kim, Yongin-si (KR); Hanbit Kim, Yongin-si (KR); Sungwook Woo, Yongin-si (KR); Dokyeong Lee, Yongin-si (KR); Myounggeun Cha, Yongin-si (KR); Sanggun Choi, Yongin-si (KR)

(21) Appl. No.: 19/374,527

(22) Filed: Oct. 30, 2025

(30) Foreign Application Priority Data
Nov. 5, 2024 (KR) 10-2024-0155682

(51) Int. Cl. H10K 59/121; H10K 59/12; H10K 59/123; H10K 71/40; H10K 102/00

(52) U.S. Cl. CPC H10K 59/1213; H10K 59/1201; H10K 59/1216; H10K 59/123; H10K 71/40; H10K 2102/331

(57) ABSTRACT

A display panel includes a pixel circuit arranged on a substrate and including a thin-film transistor, a capacitor, and a double contact hole, and a light-emitting element electrically connected to the pixel circuit, wherein the double contact hole includes a lower contact hole defined in a first insulating layer, a lower conductive layer arranged on a top surface of the first insulating layer and inside the lower contact hole, an inorganic material filled in a recess provided in the lower conductive layer by the lower contact hole, an intermediate conductive layer arranged on the lower conductive layer and the inorganic material, an upper contact hole defined in a second insulating layer on the first insulating layer, and an upper conductive layer arranged on a top surface of the second insulating layer and inside the upper contact hole and connected to the intermediate conductive layer.

### CROSS-REFERENCE TO RELATED APPLICATION

The present application claims priority to and the benefit of Korean Patent Application No. 10-2024-0155682, filed on Nov. 5, 2024, in the Korean Intellectual Property Office, the entire disclosure of which is incorporated herein by reference.

### BACKGROUND

### 1. Field

One or more embodiments of the present disclosure relate to a display panel, an electronic device including the same, and a method of manufacturing the display panel.

### 2. Description of the Related Art

Recently, display apparatuses have been used for various purposes. As the thicknesses and weights of display apparatuses have decreased, their range of applications of display apparatuses has been greatly expanded.

A display apparatus generally includes a display panel, and the display panel includes a display element that employs one or more pixels and one or more pixel circuits for controlling electrical signals applied to the display element. A pixel circuit includes one or more thin-film transistors (TFTs), one or more capacitors, and a plurality of wirings.

Significant research and development efforts have recently focused on the arrangement of thin-film transistors, capacitors, wirings, and contact holes to achieve high resolution and high integration of the display apparatus.

### SUMMARY

One or more aspects of embodiments of the present disclosure are directed toward a display apparatus including a display panel with high resolution and high integration, an electronic device including the display panel, and a method of manufacturing the display panel. However, aspects of the present disclosure are not limited thereto.

Additional aspects will be set forth in part in the description which follows and, in part, will be apparent from the description, or may be learned by practice of the presented embodiments.

According to one or more embodiments, a display panel includes a substrate, a pixel circuit on (e.g., arranged on) the substrate and including at least one thin-film transistor, at least one capacitor, and at least one double contact hole, and a light-emitting element electrically connected to the pixel circuit, wherein the double contact hole includes a lower contact hole defined in a first insulating layer, a lower conductive layer on (e.g., arranged on) a top surface of the first insulating layer and inside the lower contact hole, an inorganic material filled in a recess provided in the lower conductive layer by the lower contact hole, an intermediate conductive layer on (e.g., arranged on) the lower conductive layer and the inorganic material, an upper contact hole defined in a second insulating layer on the first insulating layer, and an upper conductive layer on (e.g., arranged on) a top surface of the second insulating layer and inside the upper contact hole and connected to the intermediate conductive layer.

In one or more embodiments, the inorganic material may be provided by agglomeration of nanoparticles formed of (e.g., including) a metal oxide and/or a metal. For example, the inorganic material may include agglomerated nanoparticles of a metal oxide and/or a metal.

In one or more embodiments, the inorganic material may include at least one material selected from among BaTiO₃, BaSO₃, BaSO₄, Ba(NO₃)₂, TiO₂, SiO₂, and ZnO.

In one or more embodiments, the inorganic material may include at least one material selected from among silver (Ag), gold (Au), platinum (Pt), and palladium (Pd).

In one or more embodiments, the upper contact hole may overlap the lower contact hole.

In one or more embodiments, the double contact hole may further include a protective film arranged along a shape of the lower conductive layer inside the recess and a buffer film on (e.g., arranged on) the protective film.

In one or more embodiments, the buffer film may be formed of a material different from the inorganic material.

In one or more embodiments, the at least one thin-film transistor may include a first thin-film transistor and a second thin-film transistor, and the at least one double contact hole may include a first double contact hole and a second double contact hole, wherein the first double contact hole connects a semiconductor layer of the first thin-film transistor to a pixel electrode of the light-emitting element.

In one or more embodiments, the at least one capacitor may include a first capacitor and a second capacitor, wherein the second double contact hole connects a semiconductor layer of the second thin-film transistor to the second capacitor.

In one or more embodiments, the first capacitor may overlap the first thin-film transistor.

According to one or more embodiments, a method of manufacturing a display panel includes forming a conductive layer on a substrate, forming a first insulating layer covering the conductive layer, and forming a lower contact hole through which a part of the conductive layer is exposed, forming a lower conductive layer connected to the conductive layer along an inner surface of the lower contact hole from a top surface of the first insulating layer, applying a dispersion solution in which inorganic nanoparticles are dispersed to cover the lower conductive layer on the first insulating layer, and annealing the substrate so that the inorganic nanoparticles are agglomerated and filled in a recess provided in the lower conductive layer by the lower contact hole.

In one or more embodiments, the method may further include cleaning the inorganic nanoparticles arranged outside the recess, after the annealing.

In one or more embodiments, the method may further include forming an intermediate conductive layer over the recess in which the inorganic nanoparticles are filled, forming a second insulating layer covering the intermediate conductive layer on the first insulating layer, and forming an upper contact hole through which a part of the intermediate conductive layer is exposed, and forming an upper conductive layer connected to the intermediate conductive layer along an inner surface of the upper contact hole from a top surface of the second insulating layer.

In one or more embodiments, the inorganic nanoparticles may include at least one material selected from among BaTiO₃, BaSO₃, BaSO₄, Ba(NO₃)₂, TiO₂, SiO₂, and ZnO.

In one or more embodiments, the inorganic nanoparticles may include at least one material selected from among silver (Ag), gold (Au), platinum (Pt), and palladium (Pd).

In one or more embodiments, the method may further include forming a protective film on the lower conductive layer before the applying of the dispersion solution.

In one or more embodiments, the method may further include partially filling an inner area of the lower contact hole by depositing a buffer film, which is thicker than the protective film, on the protective film by using a chemical vapor deposition method, and removing the buffer film formed on the first insulating layer, by using a chemical-mechanical polishing process.

In one or more embodiments, the buffer film may be formed of a material different from the inorganic nanoparticles.

According to one or more embodiments, an electronic device includes: a display panel including a double contact hole; and a cover unit supporting and accommodating the display panel, wherein the double contact hole includes a lower contact hole defined in a first insulating layer, a lower conductive layer on (e.g., arranged on) a top surface of the first insulating layer and inside the lower contact hole, an inorganic material filled in a recess provided in the lower conductive layer by the lower contact hole, an intermediate conductive layer on (e.g., arranged on) the lower conductive layer and the inorganic material, an upper contact hole defined in a second insulating layer on the first insulating layer, and an upper conductive layer on (e.g., arranged on) a top surface of the second insulating layer and inside the upper contact hole and connected to the intermediate conductive layer.

In one or more embodiments, the electronic device may be a smartphone or a glasses-type (kind) display device.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments will be more apparent from the following description taken in conjunction with the accompanying drawings, in which:

FIG. 1 is a plan view schematically illustrating a display panel, according to one or more embodiments of the present disclosure;

FIGS. 2A and 2B are each an equivalent circuit diagram illustrating a pixel circuit that may be provided in a display panel, according to one or more embodiments of the present disclosure;

FIG. 3 is a cross-sectional view schematically illustrating a display panel, according to one or more embodiments of the present disclosure;

FIG. 4 is a cross-sectional view schematically illustrating a double contact hole according to one or more embodiments of the present disclosure;

FIGS. 5-10 are schematic cross-sectional views sequentially illustrating a method of forming a double contact hole according to one or more embodiments of the present disclosure;

FIG. 11 is a cross-sectional view schematically illustrating a double contact hole according to one or more embodiments of the present disclosure;

FIGS. 12-15 are schematic cross-sectional views sequentially illustrating a method of forming a double contact hole according to one or more embodiments of the present disclosure;

FIG. 16 is a cross-sectional view schematically illustrating a double contact hole according to one or more embodiments of the present disclosure;

FIG. 17 is a perspective view illustrating an electronic device according to one or more embodiments of the present disclosure;

FIG. 18 is an exploded perspective view illustrating an electronic device according to one or more embodiments of the present disclosure;

FIG. 19 is a perspective view schematically illustrating an electronic device according to one or more embodiments of the present disclosure; and

FIG. 20 is an exploded view schematically illustrating an electronic device according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout the present disclosure, and duplicative descriptions thereof may not be provided for conciseness. In this regard, the presented embodiments may have different forms and should not be construed as being limited to the descriptions set forth herein. Accordingly, embodiments of the present disclosure are merely described in more detail, by referring to the drawings, to explain aspects of the present disclosure. As used herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c”, “at least one selected from among a, b, and c”, “at least one selected from among a to c”, and/or the like, may indicate only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, certain embodiments will be illustrated in the drawings and described in the detailed description. Effects and features of the disclosure, and methods for achieving them will be clarified with reference to one or more embodiments described herein in more detail with reference to the drawings. However, the disclosure is not limited to the following embodiments and may be embodied in one or more suitable forms.

Hereinafter, example embodiments will be described in more detail with reference to the accompanying drawings, wherein the same or corresponding elements are denoted by the same reference numerals/characters throughout the disclosure and a repeated description thereof may not be provided for conciseness.

Although the terms “first,” “second,” and/or the like. may be used to describe one or more suitable elements, these elements should not be limited by these terms. These terms are only used to distinguish one element from another. Thus, a first element described could also be termed as a second or third element without departing from the spirit and scope of the disclosure.

As used herein, the singular forms “a,” “an,” “one,” and “the” are intended to include the plural forms as well, unless the context clearly indicates otherwise.

It will be understood that the terms “include(s)/including” and/or “comprise(s)/comprising” and/or “have/has/having” are intended to indicate the existence of the features or elements described in the disclosure, and are not intended to preclude the possibility that one or more other features or elements may exist or may be added. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. Further, the use of “may” when describing embodiments of the present disclosure refers to “one or more embodiments of the present disclosure.

It will be further understood that, if (e.g., when) a layer, region, or component is referred to as being “on” another layer, region, or component, it may be directly on the other layer, region, or component, or may be indirectly on the other layer, region, or component with one or more intervening layers, regions, or components therebetween. In contrast, if (e.g., when) an element is referred to as being “directly on” another element, there are no intervening element present therebetween.

Also, sizes of components in the drawings may be exaggerated or reduced for convenience of explanation. For example, because sizes and thicknesses of components in the drawings may be illustrated for convenience of explanation, embodiments of the disclosure are not limited thereto.

If (e.g., when) a certain embodiment may be implemented differently, a specific process order may be different from the described order. For example, two consecutively described processes may be performed substantially at the same time or may be performed in an order opposite to the described order.

It will be understood that if (e.g., when) a layer, region, or component is referred to as being “connected,” the layer, the region, or the component may be directly connected or may be indirectly connected with one or more intervening layers, regions, or components therebetween. For example, if (e.g., when) layers, regions, or components are referred to as being “electrically connected,” the layers, the regions, or the components may be directly electrically connected, or may be indirectly electrically connected with one or more intervening layers, regions, or components therebetween.

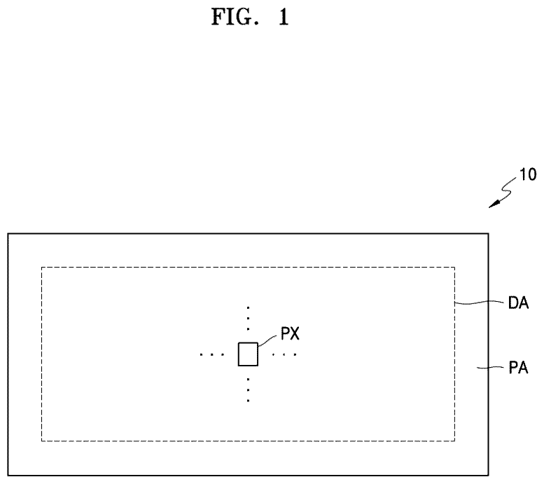

FIG. 1 is a plan view schematically illustrating a display panel, according to one or more embodiments of the present disclosure.

Referring to FIG. 1, a display panel 10 may include a display area DA and a peripheral area PA outside (e.g., around) the display area DA. The display area DA is a portion (e.g., a region) where an image is displayed, and a plurality of pixels PX may be arranged in the display area DA. The display area DA may have any of one or more suitable shapes such as a circular shape, an elliptical shape, a polygonal shape, or a shape of a specific design. The plurality of pixels PX are implemented by one or more suitable display elements such as organic light-emitting elements, inorganic light-emitting elements, or quantum dot light-emitting elements, and the display elements may be driven by being connected to a pixel circuit.

The peripheral area PA of the display panel 10 may be arranged outside (e.g., around) the display area DA. In the peripheral area PA, a driving integrated circuit (IC) for providing an electrical signal to be applied to the display area DA may be arranged, and one or more suitable wirings for transmitting an electrical signal generated in the driving IC may be located.

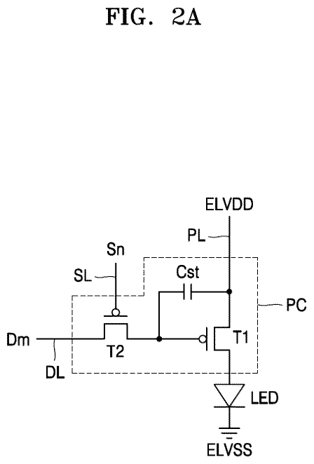

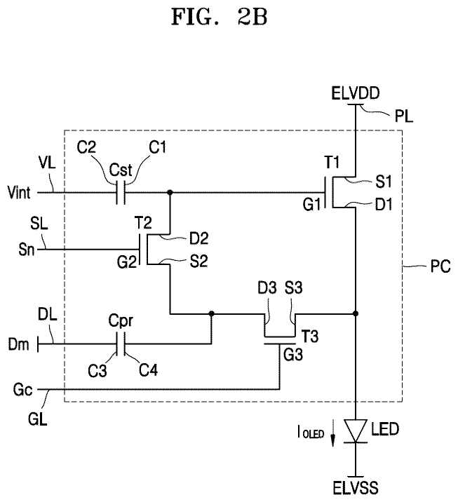

FIG. 2A and FIG. 2B are each an equivalent circuit diagram illustrating a pixel circuit of a display panel according to one or more embodiments of the present disclosure.

Referring to FIG. 2A, a pixel circuit PC may be electrically connected to a light-emitting element LED, and may include a driving transistor T1, a switching transistor T2, and a storage capacitor Cst. The pixel circuit PC may be electrically connected to a signal line and a voltage line. The signal line may include a gate line such as a scan line SL and a data line DL, and the voltage line may include a driving voltage line PL.

The driving transistor T1 may control driving current flowing through the light-emitting element LED. The driving transistor T1 may be connected to the driving voltage line PL and the storage capacitor (first capacitor) Cst. The driving transistor T1 may control the driving current flowing through the light-emitting element LED from the driving voltage line PL in response to a value of a voltage stored in the first capacitor Cst.

The switching transistor T2 may be electrically connected to the scan line SL and the data line DL. The scan line SL may provide a scan signal Sn to a gate electrode of the switching transistor T2. The switching transistor T2 may be to transmit a data signal Dm input from the data line DL to the driving transistor T1 according to the scan signal Sn input from the scan line SL.

The storage capacitor Cst may be electrically connected to the driving transistor T1 and the driving voltage line PL, and may store a voltage corresponding to a difference between a voltage received from the switching transistor T2 and a driving voltage ELVDD supplied by the driving voltage line PL.

The light-emitting element LED may be to emit light having a certain luminance due to the driving current. A first electrode of the light-emitting element LED may be electrically connected to the driving transistor T1, and a second electrode of the light-emitting element LED may be electrically connected to a common voltage line that supplies a common power supply voltage ELVSS.

Although the pixel circuit PC includes two thin-film transistors and one storage capacitor in FIG. 2A, in one or more embodiments, the pixel circuit PC may include three or more thin-film transistors.

Referring to FIG. 2B, in one or more embodiments, a pixel circuit PC may include a driving transistor T1, a switching transistor T2, a compensation transistor T3, a first capacitor Cst, and a second capacitor Cpr. The pixel circuit PC may be electrically connected to a signal line and a voltage line.

The signal line may include a scan line SL that transmits a scan signal Sn, a compensation control line GL that transmits a compensation control signal Gc, and a data line DL that transmits a data signal Dm.

The voltage line may include a driving voltage line PL and an initialization voltage line VL. The driving voltage line PL may be to transmit a driving voltage ELVDD to the driving transistor T1, and the initialization voltage line VL may be to transmit an initialization voltage Vint to the first capacitor Cst.

A driving gate electrode G1 of the driving transistor T1 may be connected to a first electrode C1 of the first capacitor Cst, a source electrode S1 of the driving transistor T1 may be connected to the driving voltage line PL, and a driving drain electrode D1 of the driving transistor T1 may be electrically connected to a pixel electrode of a light-emitting element LED. The driving transistor T1 receives the data signal Dm and supplies driving current I_{OLED} to the light-emitting element LED according to a switching operation of the switching transistor T2.

A switching gate electrode G2 of the switching transistor T2 is connected to the scan line SL, a switching source electrode S2 of the switching transistor T2 is connected to the data line DL via the second capacitor Cpr, and a switching drain electrode D2 of the switching transistor T2 is connected to the driving gate electrode G1 of the driving transistor T1. The switching transistor T2 may be turned on according to the scan signal Sn received through the scan line SL and may perform a switching operation of transmitting the data signal Dm transmitted through the data line DL to the driving transistor T1.

A compensation gate electrode G3 of the compensation transistor T3 is connected to the compensation control line GL, a compensation source electrode S3 of the compensation transistor T3 is connected to the pixel electrode of the light-emitting element LED, and a compensation drain electrode D3 of the compensation transistor T3 is connected to the data line DL via the second capacitor Cpr. The compensation transistor T3 is turned on by the compensation control signal Gc applied to the compensation gate electrode G3.

The first capacitor Cst may be connected between the driving gate electrode G1 of the driving transistor T1 and the initialization voltage line VL that supplies the initialization voltage Vint and may function as a storage capacitor. In this regard, the first electrode C1 of the first capacitor Cst may be connected to the driving gate electrode G1 of the driving transistor T1, and a second electrode C2 of the first capacitor Cst may be connected to the initialization voltage line VL.

The second capacitor Cpr may be connected between the switching source electrode S2 of the switching transistor T2 and the data line DL that supplies the data signal Dm and may function as a programming capacitor. In this regard, a third electrode C3 of the second capacitor Cpr may be connected to the data line DL, and a fourth electrode C4 of the second capacitor Cpr may be connected to the switching source electrode S2 of the switching transistor T2.

Due to the operation of the switching transistor T2, the data signal Dm applied to the second capacitor Cpr is applied to the first capacitor Cst to determine a driving gate voltage applied to the driving gate electrode G1 of the driving transistor T1, and the driving transistor T1 is turned on by the driving gate voltage. Accordingly, the light-emitting element LED may receive the driving current I_{OLED} from the driving transistor T1 to emit light.

In FIG. 2B, the source electrodes S1, S2, and S3 and the drain electrodes D1, D2, and D3 may be interchangeably arranged according to types (kinds) of transistors. Also, although the driving transistor T1, the switching transistor T2, and the compensation transistor T3 are all nMOS transistors in FIG. 2B, embodiments of the disclosure are not limited thereto. For example, the driving transistor T1, the switching transistor T2, and the compensation transistor T3 may be all pMOS transistors. In one or more embodiments, one or more suitable modifications may be made. For example, some of the driving transistor T1, the switching transistor T2, and the compensation transistor T3 may be nMOS transistors, and the rest may be pMOS transistors.

Although three thin-film transistors and two capacitors are illustrated in one or more embodiments of FIG. 2B, embodiments of the disclosure are not limited thereto, and the number of thin-film transistors and the number of capacitors may be changed in one or more suitable ways.

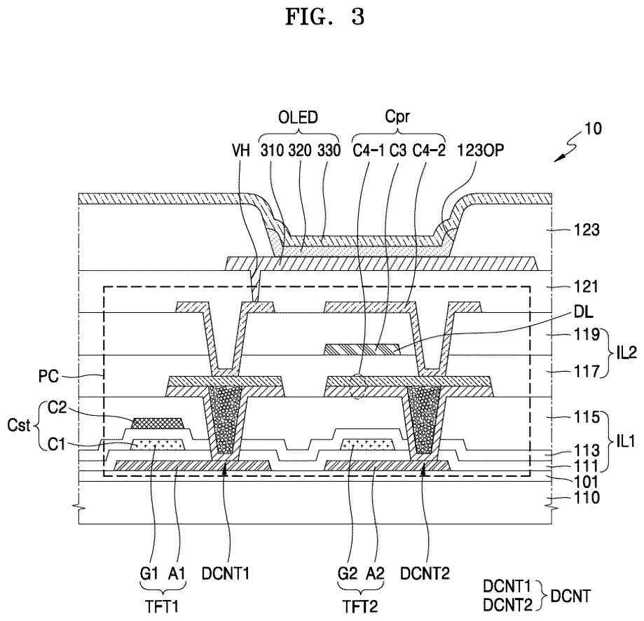

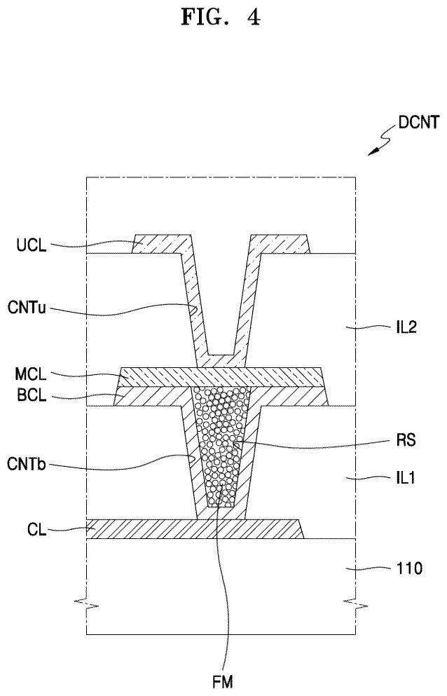

FIG. 3 is a cross-sectional view schematically illustrating a display panel according to one or more embodiments of the present disclosure. FIG. 4 is a view schematically illustrating a double contact hole of a display panel according to one or more embodiments of the present disclosure.

Referring to FIG. 3, in one or more embodiments, a display panel 10 may include a pixel circuit PC arranged on a substrate 110, and an organic light-emitting diode OLED as a light-emitting element connected to the pixel circuit PC. The pixel circuit PC according to one or more embodiments may include a first thin-film transistor TFT1, a second thin-film transistor TFT2, a first capacitor Cst, a second capacitor Cpr, and at least one double contact hole DCNT.

The first thin-film transistor TFT1 is a driving transistor and may include a first semiconductor layer A1 and a first gate electrode G1. The second thin-film transistor TFT2 is a compensation transistor and may include a second semiconductor layer A2 and a second gate electrode G2. The first capacitor Cst may include a first electrode C1 and a second electrode C2. The second capacitor Cpr may include a third electrode C3, a fourth-first electrode C4-1, and a fourth-second electrode C4-2.

The substrate 110 may include glass, a metal, or a polymer resin. In one or more embodiments, the substrate 110 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. In one or more embodiments, the substrate 110 may have a multi-layer structure including two layers each including one or more of the above polymer resins and an inorganic layer arranged between the two layers.

A buffer layer 101 may be arranged on the substrate 110. The buffer layer 101 may be an inorganic insulating layer including an inorganic insulating material such as silicon nitride and/or silicon oxide, and may have a single or multi-layer structure including the above material.

The first semiconductor layer A1 and the second semiconductor layer A2 may be arranged on the buffer layer 101. Each of the first semiconductor layer A1 and the second semiconductor layer A2 may be independently formed of a silicon semiconductor material or an oxide semiconductor material. Each of the first semiconductor layer A1 and the second semiconductor layer A2 may include a channel region, and a source region and a drain region separately arranged on two sides (e.g., two opposite sides) of the channel region. The source region and the drain region may be regions doped with impurities, and the impurities may include N-type (kind) impurities or P-type (kind) impurities. The source region and the drain region may respectively correspond to a source electrode and a drain electrode. Although the first semiconductor layer A1 and the second semiconductor layer A2 are spaced and/or apart (e.g., spaced apart or separated) from each other in the drawings, in one or more embodiments, the first semiconductor layer A1 and the second semiconductor layer A2 may be integrally connected to each other.

A gate insulating film 111 may be provided on the buffer layer 101 to cover the first semiconductor layer A1 and the second semiconductor layer A2. The gate insulating film 111 may include an inorganic insulating material such as silicon oxide (SiO₂), silicon nitride (SiNₓ), and/or silicon oxynitride (SiON), and may have a single or multi-layer structure including one or more of the above materials.

The first gate electrode G1 and the second gate electrode G2 may be arranged on the gate insulating film 111. The first gate electrode G1 and the second gate electrode G2 may respectively overlap the channel regions of the first semiconductor layer A1 and the second semiconductor layer A2. Each of the first gate electrode G1 and the second gate electrode G2 may include molybdenum (Mo), aluminum (Al), copper (Cu), and/or titanium (Ti), and may have a single or multi-layer structure.

The first gate electrode G1 may function as a gate electrode of the first thin-film transistor T1 (see FIGS. 2A and 2B) and may also function as the first electrode C1 of the first capacitor Cst (see FIGS. 2A and 2B). For example, the first gate electrode G1 and the first electrode C1 may be integrally formed with each other. As the first gate electrode G1 and the first electrode C1 are integrally formed with each other, the first gate electrode G1 and the first capacitor Cst overlap each other, thereby enabling high integration.

A first interlayer insulating film 113 may be arranged on the gate insulating film 111 to cover the first gate electrode G1 and the second gate electrode G2. The first interlayer insulating film 113 may include an inorganic insulating material such as silicon oxide (SiO₂), silicon nitride (SiNₓ), and/or silicon oxynitride (SiON), and may have a single or multi-layer structure including one or more of the above materials.

The second electrode C2 of the first capacitor Cst may be arranged on the first interlayer insulating film 113 to overlap the first gate electrode G1. As described above, the first gate electrode G1 may be the first electrode C1 of the first capacitor Cst.

A second interlayer insulating film 115 may be arranged on the first interlayer insulating film 113 to cover the second electrode C2 of the first capacitor Cst. The second interlayer insulating film 115 may include an inorganic insulating material such as silicon oxide (SiO₂), silicon nitride (SiNₓ), and/or silicon oxynitride (SiON), and may have a single or multi-layer structure including one or more of the above materials. The gate insulating film 111, the first interlayer insulating film 113, and the second interlayer insulating film 115 may constitute a first insulating layer IL1.

The fourth-first electrode C4-1 of the second capacitor Cpr may be arranged on the second interlayer insulating film 115. The fourth-first electrode C4-1 may have a multi-layer structure. The fourth-first electrode C4-1 may be electrically connected to the second semiconductor layer A2 of the second thin-film transistor TFT2.

A third interlayer insulating film 117 may be arranged on the second interlayer insulating film 115 to cover the fourth-first electrode C4-1. The third interlayer insulating film 117 may include an inorganic insulating material such as silicon oxide (SiO₂), silicon nitride (SiNₓ), and/or silicon oxynitride (SiON), and may have a single or multi-layer structure including one or more of the above materials.

The third electrode C3 of the second capacitor Cpr and the data line DL may be arranged on the third interlayer insulating film 117. The third electrode C3 may be provided as a part of the data line DL. The third electrode C3 may overlap the fourth-first electrode C4-1.

A fourth interlayer insulating film 119 may be arranged on the third interlayer insulating film 117 to cover the third electrode C3. The fourth interlayer insulating film 119 may include an inorganic insulating material such as silicon oxide (SiO₂), silicon nitride (SiNₓ), and/or silicon oxynitride (SiON), and may have a single or multi-layer structure including one or more of the above materials. The third interlayer insulating film 117 and the fourth interlayer insulating film 119 may constitute a second insulating layer IL2.

The fourth-second electrode C4-2 of the second capacitor Cpr may be arranged on the fourth interlayer insulating film 119. The fourth-second electrode C4-2 may be electrically connected to the fourth-first electrode C4-1 and the second semiconductor layer A2 of the second thin-film transistor TFT2. The fourth-second electrode C4-2 may overlap the third electrode C3 and the fourth-first electrode C4-1.

As the second capacitor Cpr has a dual structure in which the third electrode C3, the fourth-first electrode C4-1, and the fourth-second electrode C4-2 arranged on different layers overlap one another, high integration may be achieved.

Each of the third electrode C3, the fourth-first electrode C4-1, and the fourth-second electrode C4-2 of the second capacitor Cpr may include a conductive material such as molybdenum (Mo), aluminum (Al), copper (Cu), and/or titanium (Ti), and may have a single or multi-layer structure including one or more of the above materials.

A via layer 121 may be arranged on the fourth interlayer insulating film 119 to cover the fourth-second electrode C4-2 of the second capacitor Cpr. The via layer 121 may be formed of an organic insulating material such as acryl, a benzocyclobutene (BCB)-based resin, polyimide, and/or hexamethyldisiloxane (HMDSO).

The organic light-emitting diode OLED may be arranged on the via layer 121. The organic light-emitting diode OLED may include a pixel electrode 310, an intermediate layer 320 including an organic emission layer, and a counter electrode 330. Any one of the pixel electrode 310 or the counter electrode 330 of the organic light-emitting element OLED may function as an anode electrode, and the other functions as a cathode electrode.

The pixel electrode 310 may be arranged on the via layer 121. The pixel electrode 310 may include ITO, IZO, ZnO, and/or In₂O₃ having a high work function. If (e.g., when) a display apparatus (e.g., display device) is a top-emission type (kind) display apparatus, the pixel electrode 310 may further include a reflective film including silver (Ag), magnesium (Mg), aluminum (Al), platinum (Pt), palladium (Pd), gold (Au), nickel (Ni), neodymium (Nd), iridium (Ir), chromium (Cr), lithium (Li), ytterbium (Yb), or calcium (Ca), which may be used alone or in combination with each other. Also, the pixel electrode 310 may have a single or multi-layer structure including one of the above metals and/or an alloy thereof. In one or more embodiments, the pixel electrode 310 is a reflective electrode and may have an ITO/Ag/ITO structure.

A pixel-defining film 123 may be provided on the via layer 121 to cover an edge of the pixel electrode 310. The pixel-defining film 123 may include an opening 123OP through which a central portion of the pixel electrode 310 is exposed.

Because the intermediate layer 320 including the organic emission layer is arranged in the opening 123OP of the pixel-defining film 123, an emission area of the organic light-emitting diode OLED may be defined by the opening 123OP of the pixel-defining film 123. Also, the pixel-defining film 123 may increase a distance between an edge of the pixel electrode 310 and the counter electrode 330 over the pixel electrode 310, to prevent or reduce an arc and/or the like from occurring at the edge of the pixel electrode 310. The pixel-defining film 123 may be formed of at least one organic insulating material selected from the group consisting of polyimide, polyamide, an acrylic resin, a BCB-based resin, and a phenolic resin, by using spin coating and/or the like.

At least a part of the intermediate layer 320 of the organic light-emitting diode OLED may be located in the opening 123OP of the pixel-defining film 123. The intermediate layer 320 may include an organic material including a fluorescent or phosphorescent material that emits red, green, blue, or white light. The intermediate layer 320 may include the organic emission layer formed of a low molecular weight organic material or a high molecular weight organic material, and functional layers such as a hole transport layer (HTL), a hole injection layer (HIL), an electron transport layer (ETL), and an electron injection layer (EIL) may be selectively arranged under and/or over the organic emission layer.

The counter electrode 330 may be a light-transmitting electrode or a reflective electrode. For example, in one or more embodiments, the counter electrode 330 may be a transparent or semitransparent electrode, and may include a metal thin film having a low work function including Li, Ca, LiF, Al, Ag, Mg, or a compound thereof. Also, the counter electrode 330 may further include a transparent conductive oxide (TCO) film such as ITO, IZO, ZnO, or In₂O₃ located on the metal thin film. The counter electrode 330 may be integrally formed over the entire display area, and may be arranged on the intermediate layer 320 and the pixel-defining film 123.

In one or more embodiments, the double contact hole DCNT may be arranged between the substrate 110 of the display panel 10 and the organic light-emitting diode OLED. The double contact hole DCNT may refer to a contact hole in which a lower contact hole CNTb and an upper contact hole CNTu overlap each other and are connected by an intermediate conductive layer MCL (see FIG. 4). The double contact hole DCNT may connect a light-emitting element to a component of the pixel circuit PC, or may connect wirings connected to the pixel circuit PC to a component of the pixel circuit PC or components of the pixel circuit PC.

Referring to FIG. 4, the double contact hole DCNT may include the lower contact hole CNTb, a lower conductive layer BCL, an inorganic material FM, the intermediate conductive layer MCL, the upper contact hole CNTu, and an upper conductive layer UCL.

The lower contact hole CNTb may be defined in a first insulating layer IL1 to expose a part of a conductive layer CL arranged on the substrate 110. The lower contact hole CNTb may be a hole passing through the first insulating layer IL1.

The lower conductive layer BCL may be arranged inside the lower contact hole CNTb to be electrically connected to the conductive layer CL arranged in a lower portion of the first insulating layer IL1. The lower conductive layer BCL may be arranged on an inner surface of the lower contact hole CNTb from a top surface of the first insulating layer IL1.

A recess RS recessed toward the substrate 110 may be provided in an area where the lower conductive layer BCL is arranged inside the lower contact hole CNTb, and the inorganic material FM may be filled in the recess RS.

The inorganic material FM filled in the recess RS may be formed by agglomeration of nanoparticles. The inorganic material FM may be an inorganic insulating material or a metal material. The inorganic material FM may be formed by agglomerating nanoparticles such as BaTiO₃, BaSO₃, BaSO₄, Ba(NO₃)₂, TiO₂, SiO₂, and/or ZnO, each of which is a metal oxide, or may be formed of metal nanoparticles such as Ag, Au, Pt, and/or Pd nanoparticles.

If (e.g., when) a thickness of the first insulating layer IL1 increases, not only a depth of the lower contact hole CNTb but also a width of the lower contact hole CNTb may need to be large in a process. In this case, the lower conductive layer BCL may not be entirely filled in the lower contact hole CNTb, and the recess RS may be formed. If (e.g., when) the recess RS is not filled or is filled with an organic material, robustness may not be ensured or out-gassing may occur in a subsequent process. In the present embodiment, because the recess RS provided in the lower contact hole CNTb is filled with inorganic nanoparticles, the display panel having robustness and high reliability may be formed.

The intermediate conductive layer MCL may be arranged on the lower conductive layer BCL to correspond to the lower contact hole CNTb. The intermediate conductive layer MCL may be provided on the lower conductive layer BCL to cover the inorganic material FM. The lower conductive layer BCL and the intermediate conductive layer MCL may be covered by a second insulating layer IL2.

The upper contact hole CNTu may be defined in the second insulating layer IL2 to expose a part of the intermediate conductive layer MCL. The upper contact hole CNTu may be a hole passing through the second insulating layer IL2.

The upper conductive layer UCL may be arranged inside the upper contact hole CNTu to be electrically connected to the intermediate conductive layer MCL arranged in a lower portion of the second insulating layer IL2. The upper conductive layer UCL may be electrically connected to the lower conductive layer BCL through the intermediate conductive layer MCL.

Because the intermediate conductive layer MCL is arranged between the upper contact hole CNTu and the lower contact hole CNTb, the upper contact hole CNTu may overlap the lower contact hole CNTb. Due to this structure, the area occupied by the double contact hole DCNT may be reduced, thereby enabling high integration.

Each of the lower conductive layer BCL, the intermediate conductive layer MCL, and the upper conductive layer UCL may include a conductive material such as molybdenum (Mo), aluminum (Al), copper (Cu), titanium (Ti), and/or a conductive oxide, and may have a single or multi-layer structure. The lower conductive layer BCL, the intermediate conductive layer MCL, and the upper conductive layer UCL may be formed of the same material or at least one of the lower conductive layer BCL, the intermediate conductive layer MCL, or the upper conductive layer UCL may be formed of a different material.

Each of the first insulating layer IL1 and the second insulating layer IL2 may include an inorganic insulating material such as silicon oxide (SiO₂), silicon nitride (SiNₓ), and/or silicon oxynitride (SiON), and may have a single or multi-layer structure including one or more of the above materials.

In order to achieve high integration of the display panel, many layers may be introduced, and a sum of thicknesses of the first insulating layer IL1 and the second insulating layer IL2 may exceed 2 μm. In this case, there are process limitations in forming a contact hole for directly connecting a member arranged on the second insulating layer IL2 to a member arranged in a lower portion of the first insulating layer IL1. In the display panel according to embodiments of the present disclosure, a process may be facilitated and a space may be secured by introducing the double contact hole DCNT.

Referring back to FIG. 3, the display panel 10 may include a first double contact hole DCNT1 and a second double contact hole DCNT2.

The first insulating layer IL1 may be provided by stacking the gate insulating film 111, the first interlayer insulating film 113, and the second interlayer insulating film 115, and the second insulating layer IL2 may be provided by stacking the third interlayer insulating film 117 and the fourth interlayer insulating film 119.

A lower contact hole of each of the first double contact hole DCNT1 and the second double contact hole DCNT2 may pass through the gate insulating film 111, the first interlayer insulating film 113, and the second interlayer insulating film 115 of the first insulating layer IL1, and an upper contact hole of each of the first double contact hole DCNT1 and the second double contact hole DCNT2 may pass through the third interlayer insulating film 117 and the fourth interlayer insulating film 119 of the second insulating layer IL2.

The first double contact hole DCNT1 may electrically connect the first semiconductor layer A1 of the first thin-film transistor TFT1 to the pixel electrode 310. A lower conductive layer of the first double contact hole DCNT1 is arranged on the second interlayer insulating film 115 and is connected to the first semiconductor layer A1 through the lower contact hole. An upper conductive layer of the first double contact hole DCNT1 may be arranged on the fourth interlayer insulating film 119, and may be connected to an intermediate conductive layer arranged on the lower conductive layer. The pixel electrode may be connected to the upper conductive layer of the first double contact hole DCNT1 through a via hole VH passing through the via layer 121.

The second double contact hole DCNT2 may electrically connect the second semiconductor layer A2 of the second thin-film transistor TFT2 to the second capacitor Cpr.

A lower conductive layer of the second double contact hole DCNT2 is arranged on the second interlayer insulating film 115, and is connected to the second semiconductor layer A2 through the lower contact hole. The lower conductive layer of the second double contact hole DCNT2 may be connected to the fourth-first electrode C4-1 of the second capacitor Cpr. For example, the lower conductive layer of the second double contact hole DCNT2 may constitute a part of the fourth-first electrode C4-1. The fourth-first electrode C4-1 may be provided by stacking the lower conductive layer and an intermediate conductive layer.

An upper conductive layer of the second double contact hole DCNT2 may be arranged on the fourth interlayer insulating film 119, and may be connected to the intermediate conductive layer arranged on the lower conductive layer through the upper contact hole. The upper conductive layer of the second double contact hole DCNT2 may be connected to the fourth-second electrode C4-2. For example, the upper conductive electrode of the second double contact hole DCNT2 may be integrally provided with the fourth-second electrode C4-2.

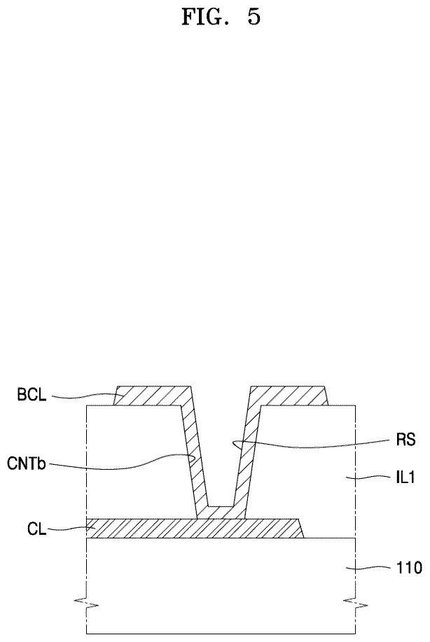

FIGS. 5 to 10 are cross-sectional views sequentially illustrating a method of forming a double contact hole according to one or more embodiments of the present disclosure.

Referring to FIG. 5, a conductive layer CL is formed on a substrate 110. The conductive layer CL may be a metal layer or a semiconductor layer. The conductive layer CL may be formed by depositing a conductive material on the entire surface of the substrate 110 and perform patterning through a photolithography process.

Next, a first insulating layer IL1 is formed on the substrate 110 to cover the conductive layer CL. The first insulating layer IL1 may be formed of an inorganic insulating material such as silicon oxide (SiO₂), silicon nitride (SiNₓ), and/or silicon oxynitride (SiON), and may be formed by using a deposition method such as chemical vapor deposition or atomic layer deposition (ALD).

Next, a lower contact hole CNTb passing through the first insulating layer IL1 is formed. The lower contact hole CNTb may be formed to expose at least a part of the conductive layer CL. The lower contact hole CNTb may be patterned through a photolithography process.

Next, a lower conductive layer BCL is formed on the first insulating layer IL1. In order to form the lower conductive layer BCL, a conductive material may be deposited on a top surface of the first insulating layer IL1 by using any of one or more suitable deposition methods, such as chemical vapor deposition or sputtering, and may be patterned through a photolithography process. The lower conductive layer BCL may be formed to fill an inner surface of the lower contact hole CNTb, and may be connected to the conductive layer CL. The lower conductive layer BCL may be deposited on the inner surface of the lower contact hole CNTb, and a recess RS recessed toward the substrate 110 may be formed in the lower contact hole CNTb.

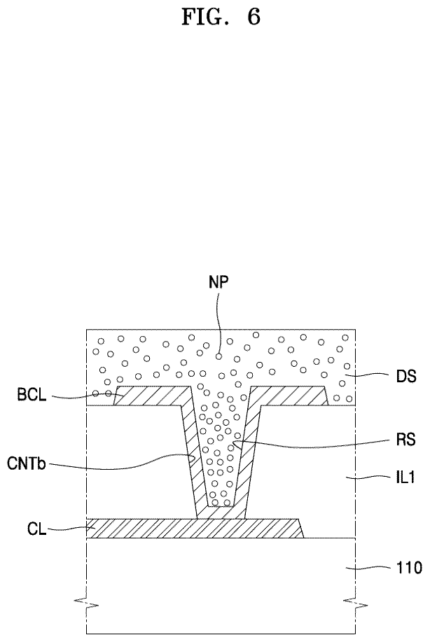

Referring to FIG. 6, a coating process is performed so that a dispersion solution DS in which inorganic nanoparticles NP are dispersed is filled inside the recess RS formed inside the lower contact hole CNTb. The coating process may be performed by using any of one or more suitable methods such as spin coating, spray coating, and/or dip coating.

The inorganic nanoparticles NP may be formed of BaTiO₃, BaSO₃, BaSO₄, Ba(NO₃)₂, TiO₂, SiO₂, and/or ZnO, each of which is a metal oxide, or may be formed of metal nanoparticles such as Ag, Au, Pt, and/or Pd nanoparticles. A diameter of the inorganic nanoparticle NP may be about 10 nanometers (nm) to about 1000 nm. The dispersion solution DS may include a high molecular weight organic material, a low molecular weight organic material, or an inorganic material as a dispersant for dispersing the inorganic nanoparticles NP in a solvent such as water.

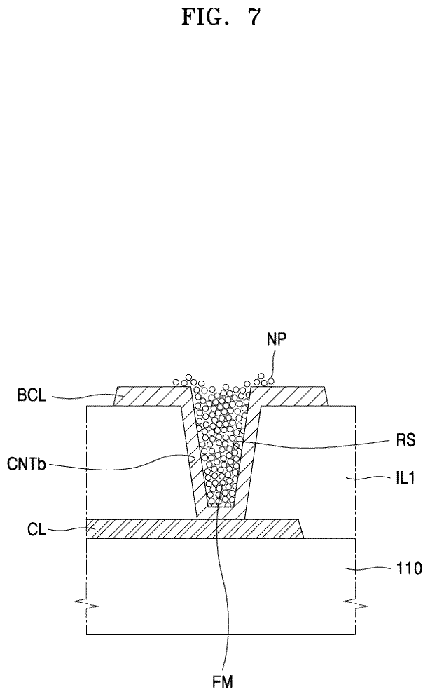

Referring to FIG. 7, after the dispersion solution is coated, an annealing process is performed. The annealing process may be a process of applying heat for a certain period of time and then cooling for a certain period of time. If (e.g., when) heat is applied by using the annealing process, the solvent of the dispersion solution evaporates, and the inorganic nanoparticles NP in the dispersion solution are agglomerated with one another. Accordingly, the inorganic material FM formed by agglomeration of inorganic nanoparticles is filled in the recess RS.

The inorganic nanoparticles NP arranged in a portion other than the inside of the recess RS may be scattered without being agglomerated due to the small number thereof. For example, the inorganic nanoparticles NP which are not agglomerated may exist on the lower conductive layer BCL.

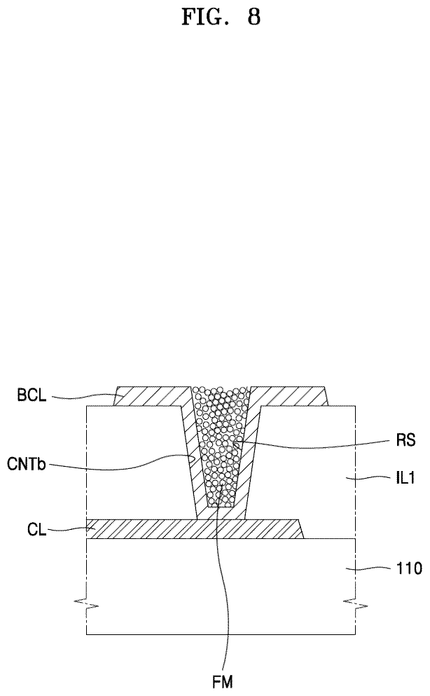

Referring to FIG. 8, the inorganic nanoparticles NP arranged in a portion other than the inside of the recess RS may be removed through a wet cleaning process and/or a dry cleaning process. Because unnecessary (e.g., excess) inorganic nanoparticles may be removed through a commonly used wet cleaning process and/or dry cleaning process, time and cost in the process may be saved.

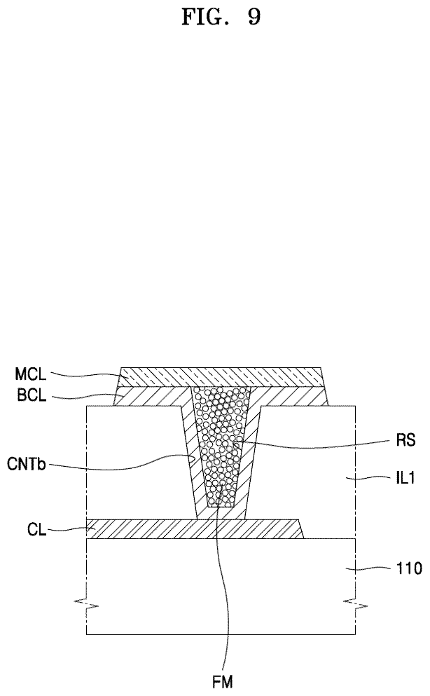

Next, referring to FIG. 9, an intermediate conductive layer MCL is formed on the lower conductive layer BCL to cover the inorganic material FM. In order to form the intermediate conductive layer MCL, a conductive material may be deposited on the first insulating layer IL1 to cover the lower conductive layer BCL by using any of one or more suitable deposition methods, and may be patterned through a photolithography process. In this case, the intermediate conductive layer MCL may be formed by using the same mask as that used to form the lower conductive layer BCL.

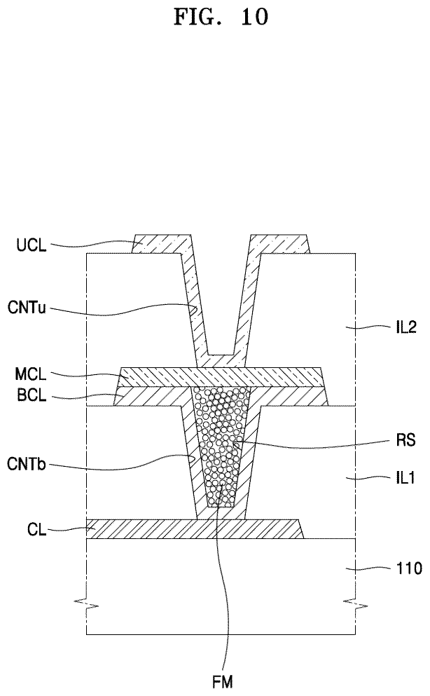

Next, referring to FIG. 10, a second insulating layer IL2 is formed on the first insulating layer IL1 to cover the intermediate conductive layer MCL. The second insulating layer IL2 may be formed of an inorganic insulating material such as silicon oxide (SiO₂), silicon nitride (SiNₓ), and/or silicon oxynitride (SiON), and may be formed by using a deposition method such as chemical vapor deposition or ALD.

Next, an upper contact hole CNTu passing through the second insulating layer IL2 is formed. The upper contact hole CNTu may be formed to expose at least a part of the intermediate conductive layer MCL. The upper contact hole CNTu may be patterned through a photolithography process. The upper contact hole CNTu may be formed to overlap the lower contact hole CNTb.

Next, an upper conductive layer UCL is formed on the second insulating layer IL2. In order to form the upper conductive layer UCL, a conductive material may be deposited on the second insulating layer IL2 by using any of one or more suitable deposition methods such as chemical vapor deposition or sputtering, and may be patterned through a photolithography process. The upper conductive layer UCL may be formed to fill an inner surface of the upper contact hole CNTu and may be connected to the intermediate conductive layer MCL.

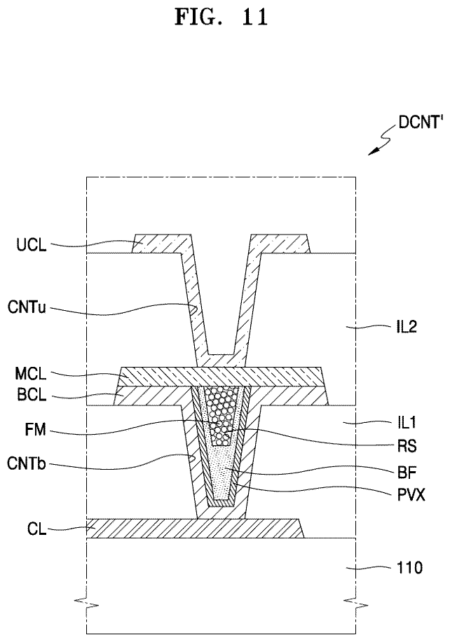

FIG. 11 is a cross-sectional view schematically illustrating a double contact hole DCNT′ according to one or more embodiments of the present disclosure. In FIG. 11, the same members as those in FIG. 4 are denoted by the same reference numerals/characters, and thus, a repeated description thereof will not be provided.

Referring to FIG. 11, the double contact hole DCNT′ includes the lower contact hole CNTb connected to the conductive layer CL and defined in the first insulating layer IL1, the lower conductive layer BCL arranged inside the lower contact hole CNTb, the upper contact hole CNTu defined in the second insulating layer IL2, and the upper conductive layer UCL arranged inside the upper contact hole CNTu.

In the present embodiment, the double contact hole DCNT′ further includes a protective film PVX and a buffer film BF each inside the lower contact hole CNTb, and the buffer film BF includes the inorganic material FM formed by agglomeration of nanoparticles in the recess RS that is recessed toward the substrate 110.

The protective film PVX for preventing or reducing damage to the lower conductive layer BCL during a process for forming the buffer film BF may be formed of a material having an etch rate different from that of the buffer film BF and the lower conductive layer BCL. For example, the protective film PVX may be formed as a thin film formed of an oxide semiconductor material such as indium zinc oxide (IZO) or indium gallium zinc oxide (IGZO), or a transparent conductive oxide. A thickness of the protective film PVX may be less than a thickness of the buffer film BF. The thickness of the protective film PVX may be about 100 angstroms (Å) to about 1000 Å. The protective film PVX may be formed by using a deposition method such as sputtering.

The buffer film BF may be arranged inside the lower contact hole CNTb to cover the protective film PVX, and may fill a portion of the lower contact hole CNTb. The buffer film BF may be formed of an inorganic insulating material such as silicon oxide (SiO₂), silicon nitride (SiNₓ), and/or silicon oxynitride (SiON), and may be formed by using a deposition method such as chemical vapor deposition or ALD. The buffer film BF may be thicker than the protective film PVX. A thickness of the buffer film BF may be determined by considering a lower stepped portion, and may be about 1000 Å to about 1000 Å.

If (e.g., when) a thickness of the first insulating layer IL1 is greater than a certain thickness, the recess formed in the lower contact hole CNTb may not be completely filled with only the inorganic material FM formed of nanoparticles. In the present embodiment, because the buffer film BF partially fills the inside of the lower contact hole CNTb, even if (e.g., when) it is difficult to fill with only the inorganic material FM, the recess RS formed in the lower contact hole CNTb may be still completely filled.

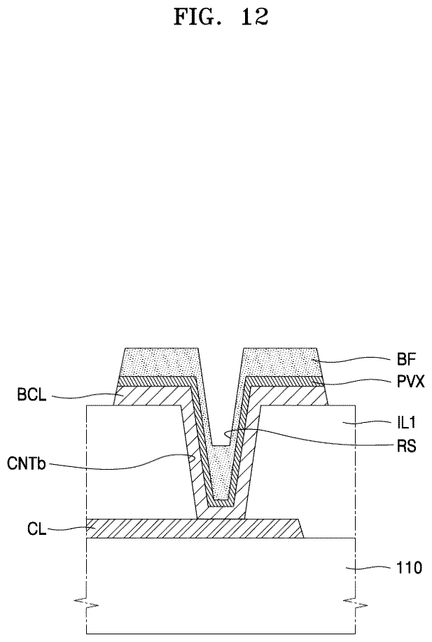

FIGS. 12 to 15 are schematic cross-sectional views sequentially illustrating a method of forming the double contact hole of FIG. 11 according to one or more embodiments of the present disclosure.

Referring to FIG. 12, after the conductive layer CL and the first insulating layer IL1 are formed on the substrate 110, the lower contact hole CNTb is formed in the first insulating layer IL1, and the lower conductive layer BCL arranged on an inner wall (e.g., inner surface) of the lower contact hole CNTb is formed.

Next, the protective film PVX is formed to cover the lower conductive layer BCL, and the buffer film BF is formed on the protective film PVX. The protective film PVX for preventing or reducing damage to the lower conductive layer BCL in a subsequent process is formed thinner than the buffer film BF. The protective film PVX may be formed of an oxide semiconductor material such as indium zinc oxide (IZO) or indium gallium zinc oxide (IGZO), or a transparent conductive oxide.

The buffer film BF is a member for filling a part of the lower contact hole CNTb and may be formed by using a chemical vapor deposition method. The buffer film BF may be formed of an inorganic insulating material such as silicon oxide (SiO₂), silicon nitride (SiNₓ), and/or silicon oxynitride (SiON). The buffer film BF may be arranged inside the lower contact hole CNTb to directly contact a top surface of the lower conductive layer BCL.

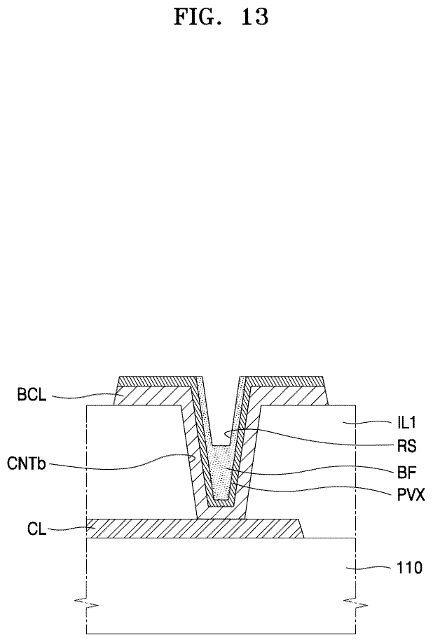

Referring to FIG. 13, the buffer film BF arranged on the first insulating layer IL1 may be removed through a chemical-mechanical polishing (CMP) process. Accordingly, the buffer film BF arranged inside the lower contact hole CNTb may not be removed, and only the buffer film BF arranged on the first insulating layer IL1 may be removed. In this regard, the protective film PVX may prevent or reduce the lower conductive layer BCL from being damaged by agents/drugs used in the CMP process.

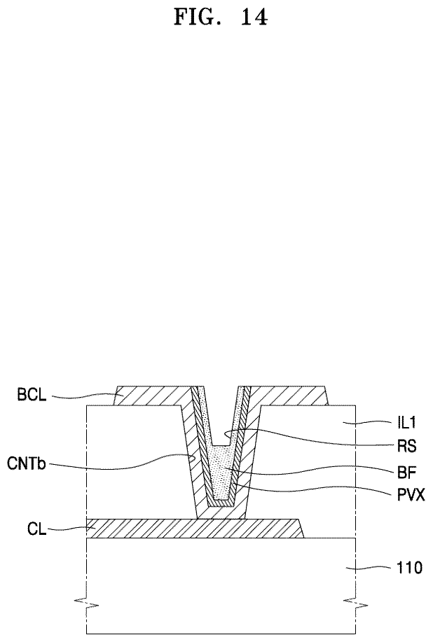

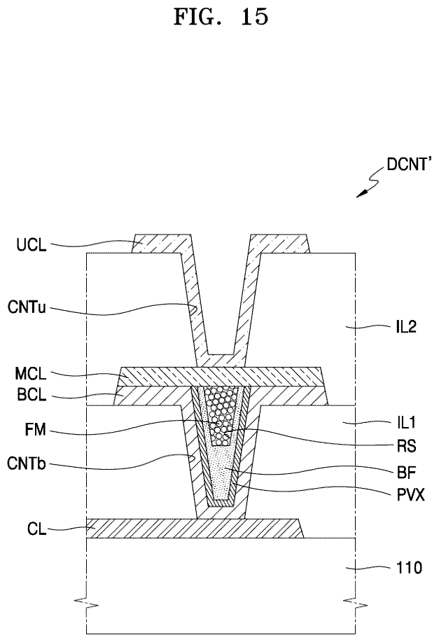

Referring to FIG. 14, the protective film PVX arranged on the first insulating layer IL1 is removed through wet etching. Next, as described with reference to FIGS. 6 to 10, the double contact hole DCNT′ of FIG. 15 may be completed by filling the inorganic material FM in the recess using a dispersion solution in which inorganic nanoparticles or metal nanoparticles are dispersed, and forming the intermediate metal layer MCL, the second insulating layer IL2, the upper contact hole CNTb, and the upper conductive layer UCL. For example, as described with reference to FIGS. 6 to 10, the double contact hole DCNT′ of FIG. 15 may be completed by filling the recess with the inorganic material FM using a dispersion solution containing inorganic nanoparticles or metal nanoparticles. This process also involves forming the intermediate metal layer MCL, the second insulating layer IL2, the upper contact hole CNTb, and the upper conductive layer UCL.

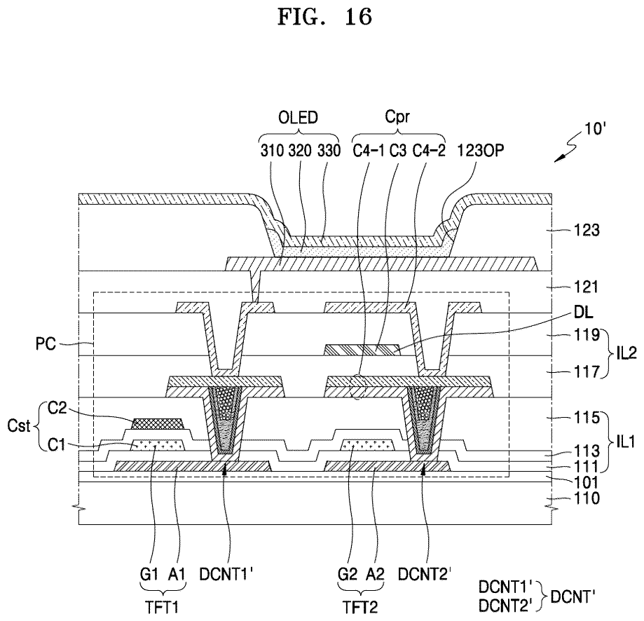

FIG. 16 is a cross-sectional view schematically illustrating a display panel to which the double contact hole of FIG. 15 is applied. In FIG. 16, the same members as those in FIG. 3 are denoted by the same reference numerals/characters.

Referring to FIG. 16, a display panel 10′ includes the pixel circuit PC arranged on the substrate 110, and the organic light-emitting diode OLED as a light-emitting element connected to the pixel circuit PC. The pixel circuit PC may include at least one thin-film transistor (e.g., TFT1 and TFT2), at least one capacitor (e.g., Cst and Cpr), and at least one double contact hole (e.g., DCNT1′ and DCNT2′).

The double contact hole DCNT′ may include a first double contact hole DCNT1′ and a second double contact hole DCNT2′. The first double contact hole DCNT1′ may connect the first semiconductor layer A1 of the first thin-film transistor TFT1 to the pixel electrode 310 of the light-emitting element.

The second double contact hole DCNT2′ may connect the second semiconductor layer A2 of the second thin-film transistor TFT2 to one electrode of the second capacitor Cpr. In more detail, a lower conductive layer of the second double contact hole DCNT2′ may be connected to the fourth-first electrode C4-1 of the second capacitor Cpr. For example, the lower conductive layer of the second double contact hole DCNT2′ may constitute a part of the fourth-first electrode C4-1. The fourth-first electrode C4-1 may be provided by stacking the lower conductive layer and an intermediate conductive layer.

An upper conductive layer of the second double contact hole DCNT2′ may be arranged on the fourth interlayer insulating film 119, and may be connected to the intermediate conductive layer arranged on the lower conductive layer through an upper contact hole. The upper conductive layer of the second double contact hole DCNT2′ may be connected to the fourth-second electrode C4-2. For example, the upper conductive layer of the second double contact hole DCNT2′ may be integrally provided with the fourth-second electrode C4-2.

In the present embodiment, a protective film covering the lower conductive layer and a buffer film may be provided inside a lower contact hole of the double contact hole DCNT′, and an inorganic material formed by agglomeration of inorganic nanoparticles may be filled in a recess provided in the buffer film. Accordingly, the display panel 10′ having robustness and high reliability may be provided.

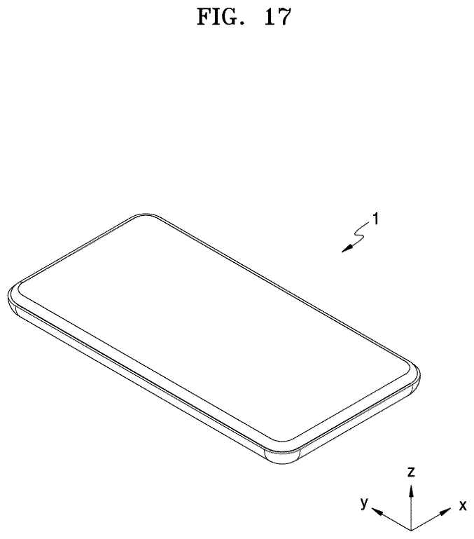

The display panels 10 and 10′ according to one or more embodiments may be included in an electronic device. According to one or more embodiments, an electronic device for displaying a moving image or a still image may be used as a display screen of not only a portable electronic device such as a mobile phone, a smartphone, a tablet personal (PC) computer, a mobile communication terminal, an electronic organizer, an electronic book, a portable multimedia player (PMP), a navigation device, or an ultra-mobile PC (UMPC) but also any of one or more suitable electronic products such as a television, a laptop computer, a monitor, an advertisement board, or an Internet of things (IoT) product. An electronic device 1 (see FIG. 17) according to one or more embodiments may be used in a wearable device such as a smart watch, a watch phone, a glasses-type (kind) display, or a head-mounted display (HMD). Also, the electronic device 1 according to one or more embodiments may be used as a center information display (CID) arranged on an instrument panel, a center fascia, or a dashboard of a vehicle, a room mirror display replacing a side-view mirror of a vehicle, or a display arranged on the back of a front seat for entertainment of a rear seat passenger of a vehicle.

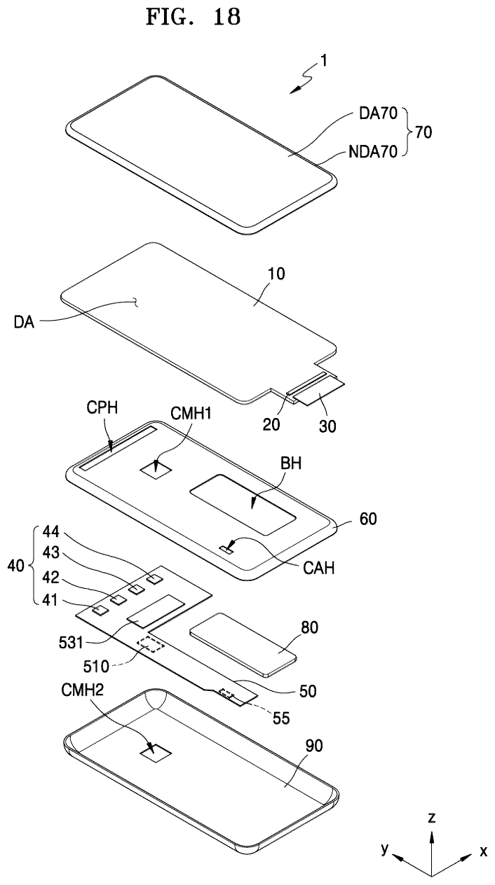

FIG. 17 is a perspective view illustrating the electronic device 1, according to one or more embodiments of the present disclosure. FIG. 18 is an exploded perspective view illustrating the electronic device 1, according to one or more embodiments.

Referring to FIG. 17 and FIG. 18, the electronic device 1 according to one or more embodiments may be a smartphone. The electronic device 1 according to one or more embodiments may include a cover window 70, the display panel 10, a data driver 20, a display circuit board 30, a component 40, a bracket 60, a main circuit board 50, a battery 80, and a lower cover 90.

In the disclosure, “left,” “right,” “upper,” and “lower” in a plan view refer to directions if (e.g., when) the display panel 10 is viewed in a direction normal (e.g., perpendicular) to the display panel 10. For example, “left” refers to a −x direction, “right” refers to a +x direction, “upper” refers to a +y direction, and “lower” refers to a −y direction.

In one or more embodiments, the electronic device 1 may have a rectangular shape in a plan view. For example, as shown in FIG. 17, the electronic device 1 may have a rectangular shape having a short side in an x direction and a long side in a y direction in a plan view. A corner where the short side in the x direction and the long side in the y direction meet each other may be rounded to have a certain curvature or formed to have a right angle. A planar shape of the electronic device 1 is not limited to a rectangular shape, and may be another polygonal shape, an elliptical shape, or an irregular shape.

The cover window 70 may be arranged on the display panel 10 to cover a top surface of the display panel 10. Accordingly, the cover window 70 may protect the top surface of the display panel 10.

The cover window 70 may include a transmissive cover portion DA70 corresponding to the display panel 10 and a light-blocking cover portion NDA70 around (e.g., surrounding) the transmissive cover portion DA70. The light-blocking cover portion NDA70 may include an opaque material for blocking light (e.g., a colored opaque material). The light-blocking cover portion NDA70 may include a pattern that may be shown to a user if (e.g., when) an image is not displayed.

The display panel 10 for providing an image may be the display panel described with reference to FIGS. 1 to 16. The display panel 10 may be arranged under the cover window 70. The display panel 10 may overlap the transmissive cover portion DA70 of the cover window 70.

The display panel 10 includes a display area DA. The display area DA where an image is displayed may include an area (hereinafter, referred to as a component area) where light emitted from the component 40 arranged under the display panel 10 is transmitted. The component 40 may include a sensor and/or a camera using visible light, infrared light, or sound.

The display panel 10 displays (outputs) information processed by the electronic device 1. For example, the display panel 10 may display execution screen information of an application driven by the electronic device 1 or user interface (UI) or graphical user interface (GUI) information according to the execution screen information.

The display panel 10 may be a light-emitting display panel including a light-emitting diode. The light-emitting diode may include an organic light-emitting diode including an organic emission layer. In one or more embodiments, the light-emitting diode may be an inorganic light-emitting diode including an inorganic material. The inorganic light-emitting diode may include a P-N junction diode including inorganic semiconductor-based materials. When a voltage is applied to a P-N junction diode in a forward direction, holes and electrons may be injected, and energy generated by recombination of the holes and electrons may be converted into light energy to emit light of a certain color. The inorganic light-emitting diode may have a width of several to hundreds of micrometers, and in one or more embodiments, the inorganic light-emitting diode may be referred to as a micro-LED.

The display panel 10 may be a rigid display panel that is rigid and is not easily bent, or a flexible display panel that is flexible and may be easily bent, folded, or rolled. For example, in one or more embodiments, the display panel 10 may be a foldable display panel that may be folded and unfolded, a curved display panel having a curved display surface, a bended display panel in which a portion other than a display surface is bent, a rollable display panel that may be rolled or unrolled, or a stretchable display panel that may be stretched.

In one or more embodiments, the display panel 10 may be a transparent display panel that is transparent so that an object or a background arranged on a bottom surface of the display panel 10 is viewed from the top surface of the display panel 10. In one or more embodiments, the display panel 10 may be a reflective display panel capable of reflecting an object or a background on the top surface of the display panel 10.

In one or more embodiments, the data driver 20 may be mounted as an integrated circuit (IC) on the display panel 10. In one or more embodiments, the data driver 20 may be arranged on the display circuit board 30.

The display circuit board 30 may be attached to a (e.g., one) side of the display panel 10. The display circuit board 30 may be a flexible printed circuit board (FPCB) that may be bent, a rigid printed circuit board (PCB) that is hard and not easily bent, or a composite printed circuit board including both (e.g., simultaneously) a rigid printed circuit board and a flexible printed circuit board.

In one or more embodiments, a touch sensor driver may be arranged on the display circuit board 30. The touch sensor driver may be formed as an IC. The touch sensor driver may be attached to the display circuit board 30. The touch sensor driver may be electrically connected to touch electrodes of a touchscreen layer of the display panel 10 through the display circuit board 30.

The touchscreen layer of the display panel 10 may detect a touch input of the user by using at least one of one or more suitable touch methods such as a resistive method or a capacitive method. For example, if (e.g., when) the touchscreen layer of the display panel 10 detects a touch input of the user by using a capacitive method, the touch sensor driver may determine whether the user touches by applying driving signals to driving electrodes from among the touch electrodes and detecting voltages charged in mutual capacitance between the driving electrodes and sensing electrodes through the sensing electrodes from among the touch electrodes. The user's touch may include a contact touch and a proximity touch. The contact touch refers to that an object such as the user's finger or a pen directly contacts the cover window 70 arranged on the touchscreen layer. The proximity touch refers to that an object such as the user's finger or a pen is arranged close to the cover window 70, such as hovering. The touch sensor driver may be to transmit sensor data to a main processor 510 according to the detected voltages, and the main processor 510 may calculate touch coordinates where the touch input occurs by analyzing the sensor data.

A controller for supplying driving voltages for driving pixels of the display panel 10, a gate driver, and the data driver 20 may be arranged on the display circuit board 30.

The bracket 60 for supporting the display panel 10 may be arranged under the display panel 10. The bracket 60 may include plastic, metal, or both (e.g., simultaneously) plastic and metal. A first camera hole CMH1 into which a camera device 531 is inserted, a battery hole BH in which the battery 80 is arranged, and a cable hole CAH through which a cable connected to the display circuit board 30 passes may be formed in the bracket 60. A component hole CPH overlapping the display panel 10 may be formed in the bracket 60. The component hole CPH may overlap the components 40 of the main circuit board 50 in a third direction (z direction). In one or more embodiments, the display area DA of the display panel 10 may overlap the components 40 of the main circuit board 50 in the third direction (the z direction). In one or more embodiments, the component hole CPH may not be formed in the bracket 60.

In one or more embodiments, the components 40 may include first to fourth components 41, 42, 43, and 44 overlapping the display panel 10. The first to fourth components 41, 42, 43, and 44 may be respectively provided as a proximity sensor, an illumination sensor, an iris sensor, a facial recognition sensor, and a camera (or an image sensor). The proximity sensor using infrared rays may detect an object positioned close to a top surface of the electronic device 1, and the illumination sensor may detect a brightness of light incident on the top surface of the electronic device 1. Also, the iris sensor may capture an image of an iris of a person positioned over the top surface of the electronic device 1, and the camera may capture an image of the object positioned over the top surface of the electronic device 1. The components 40 are not limited to the proximity sensor, the illumination sensor, the iris sensor, the facial recognition sensor, and the camera, and one or more suitable sensors described below may be arranged.

The main circuit board 50 and the battery 80 may be arranged under the bracket 60. The main circuit board 50 may be a printed circuit board or a flexible printed circuit board.

The main circuit board 50 may include the main processor 510, the camera device 531, a main connector 55, and the components 40. The main processor 510 may be formed as an IC. The camera device 531 may be arranged on both (e.g., simultaneously) a top surface and a bottom surface of the main circuit board 50, and each of the main processor 510 and the main connector 55 may be independently arranged on any one of the top surface and the bottom surface of the main circuit board 50.

The main processor 510 may control all functions of the electronic device 1. For example, the main processor 510 may output digital video data to the data driver 20 through the display circuit board 30 so that the display panel 10 displays an image. The main processor 510 may receive detection data from the touch sensor driver. The main processor 510 may determine whether the user touches according to the detection data, and may perform an operation corresponding to the user's direct touch or proximity touch. The main processor 510 may be an application processor, a central processing unit, or a system chip formed as an IC.

The camera device 531 processes an image frame such as a still image or a moving image obtained by an image sensor in a camera mode and outputs the image frame to the main processor 510. The camera device 531 may include at least one of a camera sensor (e.g., CCD or CMOS), a photo sensor (or image sensor), or a laser sensor. The camera device 531 may be connected to the image sensor among the components 40 overlapping the display area DA and may process an image input to the image sensor.

A cable passing through the cable hole CAH of the bracket 60 may be connected to the main connector 55, and thus, the main circuit board 50 may be electrically connected to the display circuit board 30.

The battery 80 may be arranged so as not to overlap the main circuit board 50 in the third direction (the z direction). The battery 80 may overlap the battery hole BH of the bracket 60.

The lower cover 90 may form an outer appearance of the electronic device 1, and an opening through which a part of the display panel 10 is exposed may be formed in a front surface of the lower cover 90. The lower cover 90 has a shape whose surface corresponding to the display panel 10 is open, and may be assembled to the display panel 10. The lower cover 90 may be arranged opposite to the cover window 70 with the display panel 10 therebetween. The lower cover 90 may be arranged under the main circuit board 50 and the battery 80. The lower cover 90 may be fastened and fixed to the bracket 60. The lower cover 90 may form an outer appearance of a bottom surface of the electronic device 1. The lower cover 90 may include plastic, metal, or both (e.g., simultaneously) plastic and metal.

A second camera hole CMH2 through which a bottom surface of the camera device 530 is exposed may be formed in the lower cover 90. A position of the camera device 531 and positions of the first and second camera holes CMH1 and CMH2 corresponding to the camera device 531 are not limited to those illustrated in FIG. 17 and FIG. 18 and may be changed in one or more suitable ways.

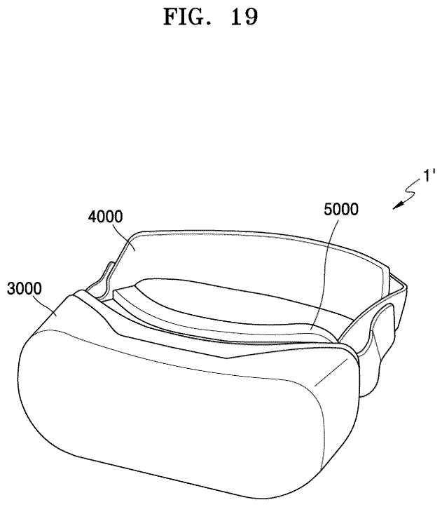

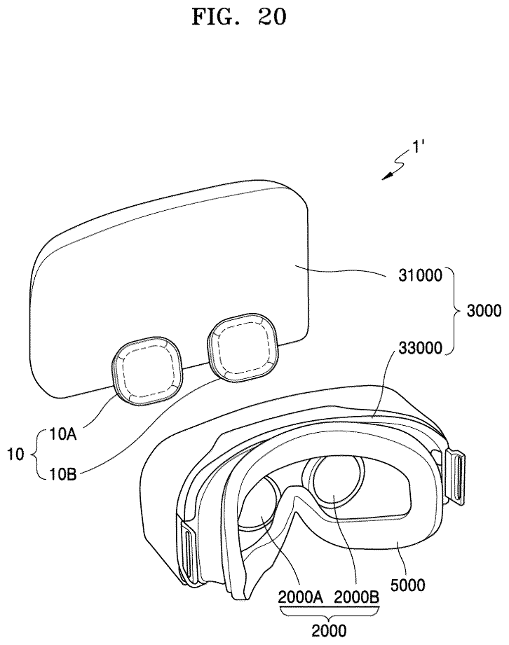

FIG. 19 is a perspective view schematically illustrating an electronic device 1′, according to one or more embodiments of the present disclosure. FIG. 20 is an exploded view schematically illustrating the electronic device 1′, according to one or more embodiments.

Referring to FIG. 19 and FIG. 20, the electronic device 1′ may be worn on the head of a user. The electronic device 1′ may provide an image in a state where the user's actual peripheral vision is blocked or in a state where the actual peripheral vision is not blocked. The user wearing the electronic device 1′ may easily immerse himself/herself in augmented reality or virtual reality. The electronic device 1′ may include the display panel 10, an optical unit 2000, a cover unit 3000, a fixing unit 4000, and a cushion unit 5000.

The display panel 10 for providing an image may be the display panel described with reference to FIGS. 1 to 16. The display panel 10 may be accommodated in the cover unit 3000. In one or more embodiments, the electronic device 1′ may include a plurality of display panels 10. For example, the electronic device 1′ may include a first display panel 10A and a second display panel 10B. In these embodiments, the first display panel 10A and the second display panel 10B may overlap a plurality of optical units 2000. The first display panel 10A may be a left-eye display panel. The second display panel 10B may be a right-eye display panel. In one or more embodiments, the electronic device 1′ may include one display panel 10. In these embodiments, the plurality of optical units 2000 may overlap one display panel 10.

The optical unit 2000 may pass light emitted from the display panel 10 therethrough. The optical unit 2000 may refract and/or reflect light emitted from the display panel 10. In one or more embodiments, the optical unit 20 may enlarge an image provided from the display panel 10. The optical unit 2000 may face the display panel 10. When the user wears the electronic device 1′, the optical unit 2000 may be arranged between the user and the display panel 10. Accordingly, the user may perceive light emitted from the display panel 10 and refracted and/or reflected by the optical unit 2000. In one or more embodiments, the optical unit 2000 may include at least one of a lens or a mirror.

In one or more embodiments, the electronic device 1′ may include the plurality of optical units 2000. For example, the electronic device 1′ may include a first optical unit 2000A and a second optical unit 2000B. In these embodiments, the first display panel 10A may face the first optical unit 2000A. The second display panel 10B may face the second optical unit 2000B. The first optical unit 2000A may be a left-eye optical unit. The second optical unit 2000B may be a right-eye optical unit. In one or more embodiments, the electronic device 1 may include one optical unit 2000.

The cover unit 3000 may accommodate the display panel 10 and the optical unit 2000 therein. The cover unit 3000 may include an inner space, and the display panel 10 and the optical unit 2000 may be arranged in the inner space. The cover unit 3000 may protect the display panel 10 and the optical unit 2000 from external impact. In one or more embodiments, the cover unit 3000 may be separated into a first cover unit 31000 and a second cover unit 33000. In one or more embodiments, the first cover unit 31000 and the second cover unit 33000 may be integrally provided with each other. In one or more embodiments, the first cover unit 31000 may be opaque. In one or more embodiments, the first cover unit 31000 may be transparent.

The cover unit 3000 may support the display panel 10 that is curved. For example, in one or more embodiments, the display panel 10 may be fixed in the cover unit 3000. Also, the cover unit 3000 may support the display panel 10 to maintain the shape of the display panel 10 that is curved.

The fixing unit 4000 may fix the cover unit 3000 to the user's head. Accordingly, the electronic device 1′ may be worn on the user's head. In one or more embodiments, a length of the fixing unit 4000 may be adjusted. For example, a length of the fixing unit 4000 may be adjusted according to a circumference of the user's head.

The fixing unit 4000 may bring the electronic device 1′ into close contact with the user's head. In one or more embodiments, the fixing unit 4000 may have elasticity. Although the fixing unit 4000 is a strap in FIG. 19, in one or more embodiments, the fixing unit 4000 may be of one or more suitable types (kinds) such as a helmet coupled to the cover unit 3000 or glasses temples connected to the cover unit 3000. The fixing unit 4000 may be connected to the cover unit 3000. In one or more embodiments, the fixing unit 4000 may be detachable from the cover unit 3000.

The cushion unit 5000 may improve the wearability on the user. When the user wears the electronic device 1, the cushion unit 5000 may be arranged between the user and the cover unit 3000. In one or more embodiments, the cushion unit 5000 may be attached to the cover unit 3000. In one or more embodiments, the cushion unit 5000 may be detachable from the cover unit 3000. In one or more embodiments, the cushion unit 5000 may not be provided.

The cushion unit 5000 may include a material whose shape may be freely changed. For example, in one or more embodiments, the cushion unit 5000 may include a polymer resin. For example, the cushion unit 5000 may include at least one of polyurethane, polycarbonate, polypropylene, or polyethylene. In one or more embodiments, the cushion unit 5000 may include a sponge foamed with a rubber liquid, a urethane-based material, or an acrylic material.

As described above, a display panel, a display apparatus (e.g., a display device) including the display panel, and an electronic device including the display apparatus and/or the display panel according to the present disclosure include a double contact hole in which a lower contact hole is filled with inorganic nanoparticles, and thus, may have robustness and high reliability. For example, the display panel and the electronic device incorporating this display panel feature a double contact hole. This double contact hole includes a lower contact hole that is filled with inorganic nanoparticles. The inclusion of inorganic nanoparticles enhances the robustness and reliability of the display panel, ensuring it can withstand various operational stresses and environmental conditions. The design of the double contact hole contributes to the overall durability and performance of the display panel, making it suitable for high-resolution and high-integration applications.

Also, because the double contact hole is formed by using a dispersion solution in which inorganic nanoparticles are dispersed, process time and cost may be saved. For example, the formation of the double contact hole utilizes a dispersion solution in which inorganic nanoparticles are dispersed. This method of using a dispersion solution not only simplifies the manufacturing process but also significantly reduces the time and cost associated with production. By efficiently filling the recesses with inorganic material and forming the necessary conductive layers, the process ensures a high-quality and reliable connection within the pixel circuit. This approach streamlines the fabrication of the display panel, making it more cost-effective and time-efficient while maintaining high standards of quality and performance.

The effects and benefits described above are examples, and the effects and benefits of the disclosure are not limited thereto.

In the context of the present application and unless otherwise defined, the terms “use,” “using,” and “used” may be considered synonymous with the terms “utilize,”“utilizing,”and “utilized,” respectively.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” or “on” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display device/apparatus, the electronic device/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by one of ordinary skill in the art that one or more suitable changes in form and details may be made therein without departing from the spirit and scope as defined by the following claims and equivalents thereof.

What is claimed is:

1. A display panel comprising:
a substrate;
a pixel circuit on the substrate and comprising:
at least one thin-film transistor;
at least one capacitor; and
at least one double contact hole; and
a light-emitting element electrically connected to the pixel circuit,
wherein the double contact hole comprises:
a lower contact hole defined in a first insulating layer;
a lower conductive layer on a top surface of the first insulating layer and inside the lower contact hole;
an inorganic material filled in a recess provided in the lower conductive layer by the lower contact hole;
an intermediate conductive layer on the lower conductive layer and the inorganic material;
an upper contact hole defined in a second insulating layer on the first insulating layer; and
an upper conductive layer on a top surface of the second insulating layer and inside the upper contact hole and connected to the intermediate conductive layer.

2. The display panel of claim 1, wherein the inorganic material comprises agglomerated nanoparticles of a metal oxide and/or a metal.

3. The display panel of claim 1, wherein the inorganic material comprises at least one material selected from among BaTiO₃, BaSO₃, BaSO₄, Ba(NO₃)₂, TiO₂, SiO₂, and ZnO.

4. The display panel of claim 1, wherein the inorganic material comprises at least one material selected from among silver, gold, platinum, and palladium.

5. The display panel of claim 1, wherein the upper contact hole overlaps the lower contact hole.

6. The display panel of claim 1, wherein the double contact hole further comprises a protective film along a shape of the lower conductive layer inside the recess and a buffer film on the protective film.

7. The display panel of claim 6, wherein the buffer film comprises a material different from the inorganic material.

8. The display panel of claim 1, wherein
the at least one thin-film transistor comprises a first thin-film transistor and a second thin-film transistor, and
the at least one double contact hole comprises a first double contact hole and a second double contact hole, and
wherein the first double contact hole connects a semiconductor layer of the first thin-film transistor to a pixel electrode of the light-emitting element.

9. The display panel of claim 8, wherein the at least one capacitor comprises a first capacitor and a second capacitor, and
wherein the second double contact hole connects a semiconductor layer of the second thin-film transistor to the second capacitor.

10. The display panel of claim 9, wherein the first capacitor overlaps the first thin-film transistor.

11. A method, comprising:
forming a conductive layer on a substrate;
forming a first insulating layer covering the conductive layer, and forming a lower contact hole through which a part of the conductive layer is exposed;
forming a lower conductive layer connected to the conductive layer along an inner surface of the lower contact hole from a top surface of the first insulating layer;
applying a dispersion solution in which inorganic nanoparticles are dispersed to cover the lower conductive layer on the first insulating layer; and
annealing the substrate so that the inorganic nanoparticles are agglomerated and filled in a recess provided in the lower conductive layer by the lower contact hole,
wherein the method is a method of manufacturing a display panel.

12. The method of claim 11, further comprising cleaning the inorganic nanoparticles arranged outside the recess, after the annealing.

13. The method of claim 11, further comprising:
forming an intermediate conductive layer over the recess in which the inorganic nanoparticles are filled;
forming a second insulating layer covering the intermediate conductive layer on the first insulating layer, and forming an upper contact hole through which a part of the intermediate conductive layer is exposed; and
forming an upper conductive layer connected to the intermediate conductive layer along an inner surface of the upper contact hole from a top surface of the second insulating layer.

14. The method of claim 11, wherein the inorganic nanoparticles comprise at least one material selected from among BaTiO₃, BaSO₃, BaSO₄, Ba(NO₃)₂, TiO₂, SiO₂, and ZnO.

15. The method of claim 11, wherein the inorganic nanoparticles comprise at least one material selected from among silver, gold, platinum, and palladium.

16. The method of claim 11, further comprising forming a protective film on the lower conductive layer before the applying of the dispersion solution.

17. The method of claim 16, further comprising:
partially filling an inner area of the lower contact hole by depositing a buffer film, which is thicker than the protective film, on the protective film, utilizing a chemical vapor deposition method; and
removing the buffer film formed, on the first insulating layer utilizing a chemical-mechanical polishing process.

18. The method of claim 17, wherein the buffer film is formed of a material different from the inorganic nanoparticles.

19. An electronic device comprising:
a display panel comprising a double contact hole; and
a cover unit supporting and accommodating the display panel,
wherein the double contact hole comprises:
a lower contact hole defined in a first insulating layer;
a lower conductive layer on a top surface of the first insulating layer and inside the lower contact hole;
an inorganic material filled in a recess provided in the lower conductive layer by the lower contact hole;
an intermediate conductive layer on the lower conductive layer and the inorganic material;
an upper contact hole defined in a second insulating layer on the first insulating layer; and
an upper conductive layer on a top surface of the second insulating layer and inside the upper contact hole and connected to the intermediate conductive layer.

20. The electronic device of claim 19, wherein the electronic device is a smartphone or a glasses-type display device.
